(19) United States
(12) Patent Application Publication
(10) Pub. No.: US 2007/0049046 A1
(43) Pub. Date: Mar. 1, 2007

(54) Oxide film filled structure, oxide film filling method, semiconductor device and manufacturing method thereof

(75) Inventors: Mahito Sawada, Tokyo (JP); Koyu Asai, Tokyo (JP); Yoshihiro Miyagawa, Tokyo (JP); Tatsunori Murata, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/502,402

(22) Filed: Aug. 11, 2006

(30) Foreign Application Priority Data
Aug. 25, 2005 (JP) 2005-243825

(51) Int. Cl. H01L 21/31

(52) U.S. Cl. 438/758

(57) ABSTRACT

The present invention aims at offering the filled structure of an oxide film etc. which can form an insulating film (oxide film) without void in a predetermined depressed portion by an economical and practical method and without increasing RF bias. According to the first invention, the oxide film filled structure is provided with the foundation (silicon substrate) having a depressed portion (trench), and the oxide film (silicon oxide film) formed in the depressed portion concerned. Here, the oxide film concerned includes the silicon oxide film region of silicon-richness in part at least.

### CROSS-REFERENCE TO RELATED APPLICATION

The present application claims priority from Japanese patent application No. 2005-243825 filed on Aug. 25, 2005, the content of which is hereby incorporated by reference into this application.

### 1. FIELD OF THE INVENTION

This invention relates to an oxide film filled structure, an oxide film filling method, a semiconductor device, and a manufacturing method of the semiconductor device, and it is applicable to a semiconductor device which has a trench where an aspect ratio is high, and a manufacturing method of the semiconductor device, for example.

### 2. DESCRIPTION OF THE BACKGROUND ART

The width of a shallow trench isolation (STI) for element isolation is becoming narrow with increasing integration density of a semiconductor device (that is, the aspect ratio of STI is becoming high). Therefore, the gap-fill process without void for the trench of the high aspect ratio concerned has been required. As a gap-fill process for STI of high aspect ratio concerned, the high-density-plasma CVD (HDP-CVD) for performing film formation and sputter etching simultaneously is used.

There are Patent References 1 to 6, Nonpatent Literature 1, etc. about HDP-CVD, and gap-fill process which combined deposition and etching.

In the HDP-CVD, source RF and RF bias are applied during the deposition. Hereby, an insulating film can be formed on the object for film formation concerned, drawing ions to the object for film formation. Source RF is the high-frequency power for generating plasma by decomposing the gasses in a reaction chamber. RF bias is the high-frequency power for drawing ions to the object for film formation.

Simultaneously with the deposition of an insulating film, in the HDP-CVD concerned, sputter etching by the ion bombardment by RF bias is performed as above-mentioned.

Film formation at the bottom of the trench concerned can be performed, sputtering the overhang part generated in an opening of the trench, in the HDP-CVD concerned. Therefore, before the opening of the trench occludes, an insulating film can be filled inside the trench. That is, the trench concerned can be filled with an insulating film without voids.

In relation to the present invention, the technology which forms the silicon nitride oxide film whose refractive index is 1.5-1.95 in a trench also exists (Patent Reference 7).

[Patent Reference 1] Japanese Unexamined Patent Publication No. 2000-306992

[Patent Reference 2] Japanese Unexamined Patent Publication No. 2003-31649

[Patent Reference 3] Japanese Granted Patent No. 2995776

[Patent Reference 4] Japanese Unexamined Patent Publication No. Hei 10-308394

[Patent Reference 5] Japanese Unexamined Patent Publication No. 2003-37103

[Patent Reference 6] Japanese Unexamined Patent Publication No. 2003-203970

[Patent Reference 7] Japanese Unexamined Patent Publication No. 2001-35914

[Nonpatent Literature 1] NANOCHIP TECHNOLOGY JOURNAL Vol2 Issue2 2004 pp 41-44

### SUMMARY OF THE INVENTION

However, as the design rule of a semiconductor device continues to shrink further (for example, when making the device after 65 nm), the aspect ratio of STI is becoming still higher. Thus, when the aspect ratio becomes still higher, the deposition rate of the overhang near the trench opening will be faster than the deposition rate at the bottom part of the trench. Therefore, the gap-fill without void in the inside of the trench is not achieved.

In order to lower the deposition rate of the overhang near the trench opening, it is possible to make RF bias high. However, when RF bias is made high, the problems shown below will occur.

The first problem is the generation of a void by the re-deposition of film formation material.

By doing sputter etching of the overhang near the opening of the trench, the film formation material with which the overhang concerned was formed is sputtered. And re-deposition of the sputtered film formation material concerned is done to the inside of the trench. Here, when RF bias is not so strong, the amount of re-deposition of the film formation material concerned decreases, and it adheres to the more upper part of the trench.

However, in the case of high aspect ratio STI, when RF bias is made high as mentioned above, the re-deposition of the film formation material is formed at the opening inside the trench (near directly under the overhang currently formed (reference 10 of FIG. 8)), and the amount of re-deposition also increases. Therefore, when RF bias is made high, the deposition rate at the upper part of the trench becomes high rather than the deposition rate at the bottom of the trench. Therefore, the gap-fill without void is not achieved (the first problem).

The second problem is the shoulder cutting of an element formation part.

The amount of sputter etching by RF bias changes with differences of pattern density (differences between roughness and fineness of a pattern). Therefore, when the film is deposited on the region in which the portion where the trench is formed densely, and the portion where the trench is formed sparsely are intermingled by the HDP-CVD, the top end of the trench of the portion where the trench is formed sparsely concerned is sputtered so much, for example (Generation of shoulder cutting. The second problem, refer to reference 11 of FIG. 8.).

Thus, the relation of the gap-fill without void in the trench whose aspect ratio is high and the shoulder cutting of the top end of the trench is trade-off. Therefore, it is not appropriate to make RF bias high from the viewpoint of the shoulder cutting of the trench top end concerned.

By each above problem, it is not best to make RF bias high.

By the way, in the method concerned in Patent Reference 1, the heat treatment is performed to the trench containing the void. Hereby, the invention concerned is aiming at dissipation of void. However, even if the heat treatment is performed, it will be very difficult to extinguish completely the void formed once. Since a prolonged heat treatment is required, it is contrary to economization of a manufacturing process.

It is impossible to form a silicon nitride oxide film in the inside of the trench where the aspect ratio is high without a void generation by the method concerned in Patent Reference 7.

By the above, it is desired that an insulating film without void can be formed in the inside of a trench without void, without generating problems otherwise (that is, without increasing RF bias), and the formation method of the insulating film concerned is economical and practical.

Then, the present invention aims at a method of filling an oxide film and a manufacturing method of a semiconductor device which can form an insulating film (oxide film) without void in a predetermined depressed portion without increasing RF bias and with an economical and practical method, and further the filled structure of an oxide film formed by the method concerned and the semiconductor device which has the filled structure of an oxide film.

In order to attain the above-mentioned purpose, an oxide film filled structure according to claim 1 concerning the present invention comprises a foundation having a depressed portion, and an oxide film which is formed in the depressed portion and includes silicon and oxygen, wherein the oxide film includes a silicon oxide film region of silicon-richness in part at least.

An oxide film filled structure according to claim 2 comprises a foundation having a depressed portion, and an oxide film which is formed in the depressed portion and includes silicon and oxygen, wherein the oxide film includes a silicon oxide film region where a refractive index exceeds 1.465 in part at least.

An oxide film filled structure according to claim 3 comprises a foundation having a depressed portion, and an oxide film which is formed in the depressed portion and includes silicon and oxygen, wherein the oxide film includes a silicon oxide film region in which the oxygen is missing as compared with stoichiometric composition in part at least.

An oxide film filled structure according to claim 4 comprises a foundation having a depressed portion, and an oxide film which is formed in the depressed portion and includes silicon and oxygen, wherein the oxide film includes a silicon oxide film region where the silicon is superfluous in part at least as compared with stoichiometric composition.

A semiconductor device according to claim 5 has the oxide film filled structure according to any one of claims 1-4.

An oxide film filling method according to claim 13 comprises the steps of (X) forming a depressed portion in a foundation, and (Y) forming an oxide film including silicon and oxygen in the depressed portion, wherein the step (Y) is a step which forms the oxide film including a silicon oxide film region of silicon-richness in part at least.

An oxide film filling method according to claim 14 comprises the steps of (A) forming a depressed portion in a foundation, and (B) forming an oxide film in the depressed portion, wherein the step (B) comprises a step of (B-1) forming the oxide film using plasma CVD method according to a condition whose flow rate ratio of O₂/SiH₄ is less than 1.5.

An oxide film filling method according to claim 15 comprises the steps of (a) forming a depressed portion in a foundation, and (b) forming an oxide film in the depressed portion, wherein the step (b) comprises a step of (b-1) forming the oxide film using plasma CVD method using hydrogen gas according to a condition whose flow rate ratio of O₂/SiH₄ is less than 2.

A manufacturing method of a semiconductor device according to claim 16 comprises a step of forming an oxide film in a depressed portion which a foundation layer has by the oxide film filling method according to any one of claims 13-15.

Since having the oxide film which includes the silicon oxide film region of silicon-richness in part at least, the oxide film including the silicon oxide film region where a refractive index exceeds 1.465 in part at least, the oxide film which includes the silicon oxide film region in which the oxygen is missing as compared with stoichiometric composition in part at least, or the oxide film including the silicon oxide film region where the silicon is superfluous as compared with stoichiometric composition in part at least in the depressed portion, oxide film filled structures described in claims 1 to 4 of the present invention can offer the oxide film filled structure that the oxide film not having the generation of void was formed in a depressed portion with a high aspect ratio.

Since having the oxide film filled structure according to claims 1 to 4, the semiconductor device according to claim 5 can offer the semiconductor device which has the above-mentioned oxide film filled structure with sufficient filling property.

Since having the step which forms in the depressed portion the oxide film which includes the silicon oxide film region of silicon-richness in part at least, the step which forms an oxide film in a depressed portion according to the condition whose flow rate ratio of O₂/SiH₄ is less than 1.5 using plasma CVD method, or the step which forms an oxide film in a depressed portion using hydrogen gas using plasma CVD method according to the condition whose flow rate ratio of O₂/SiH₄ is less than 2, the oxide film filling method described in claim 13 to claim 15 can fill an oxide film without the generation of void in a depressed portion with a high aspect ratio.

Since the manufacturing method of a semiconductor device according to claim 16 has the step which forms an oxide film in the depressed portion which a foundation layer has by the oxide film filling method according to claims 13 to 15, even if an oxide film is formed in a depressed portion with a high aspect ratio, STI which does not have void, for example can be formed.

### BRIEF DESCRIPTION OF THE DRAWINGS

FIGS. 1 to 3 are step cross-sectional views for explaining the manufacturing method of the semiconductor device concerning Embodiment 1;

FIG. 4 is a drawing of the experimental data in which the state of change of the refractive index of a silicon oxide film to change of O₂/SiH₄ flow rate ratio is shown;

FIGS. 5 to 6 are step cross-sectional views for explaining the manufacturing method of the semiconductor device concerning Embodiment 1;

FIG. 7 is a drawing of the experimental data in which the relation of O₂/SiH₄ flow rate ratio, and the aspect ratio in which the filling of an oxide film is possible is shown;

FIG. 8 is a cross-sectional view showing the state of re-deposition and shoulder cutting;

FIG. 9 is a drawing showing the flow of each step pattern concerning Embodiment 2;

FIGS. 10 to 12 are step cross-sectional views for explaining the manufacturing method of the semiconductor device concerning Embodiment 2;

FIG. 13 is a drawing of the experimental data in which a state that the composition ratio of oxygen to silicon changes by performing oxygen plasma treatment is shown;

FIG. 14 is a drawing of the experimental data for explaining the effect at the time of performing oxygen plasma treatment;

FIG. 15 is a drawing showing the flow of each step pattern concerning Embodiment 4; and

FIGS. 16 to 19 are step cross-sectional views for explaining the manufacturing method of the semiconductor device concerning Embodiment 4.

### DETAILED DESCRIPTION OF THE PREFERRED EMBODIMENTS

Inventors discovered that a film which was excellent in step coverage (that is, void is not included) was formed by lowering the flow rate ratio (=O₂/SiH₄) of oxygen (O₂) to silane (SiH₄) when forming a silicon oxide film in the depressed portions (for example, trench etc.) which exist in the front surface of a foundation. It is thought that this is because the sticking probability of a precursor for film formation decreases.

Here, the silicon oxide film formed by lowering a flow rate ratio is silicon-rich. In other words, the refractive index of the silicon oxide film concerned will exceed 1.465. In the silicon oxide film concerned, oxygen is missing as compared with stoichiometric composition. In other words further, in the silicon oxide film concerned, silicon is superfluous as compared with stoichiometric composition.

The refractive index of the silicon oxide film which is stoichiometry (it has stoichiometric composition) is about 1.465. The measurement wavelength of the refractive index is 633 nm.

Hereafter, this invention is concretely explained based on the drawings and experimental data in which the embodiment is shown.

### Embodiment 1

A manufacturing method of a semiconductor device concerning this embodiment is explained using step cross-sectional views.

First, oxide film 2 and silicon nitride film 3 are formed on silicon substrate (it can be grasped as a foundation) 1 at the order concerned.

Then, to oxide film 2, silicon nitride film 3, and silicon substrate 1 concerned, the dry etching process is performed and these are patterned to a predetermined configuration. Then, dry etching is performed to silicon substrate 1, using oxide film 2 and silicon nitride film 3 concerned as a mask.

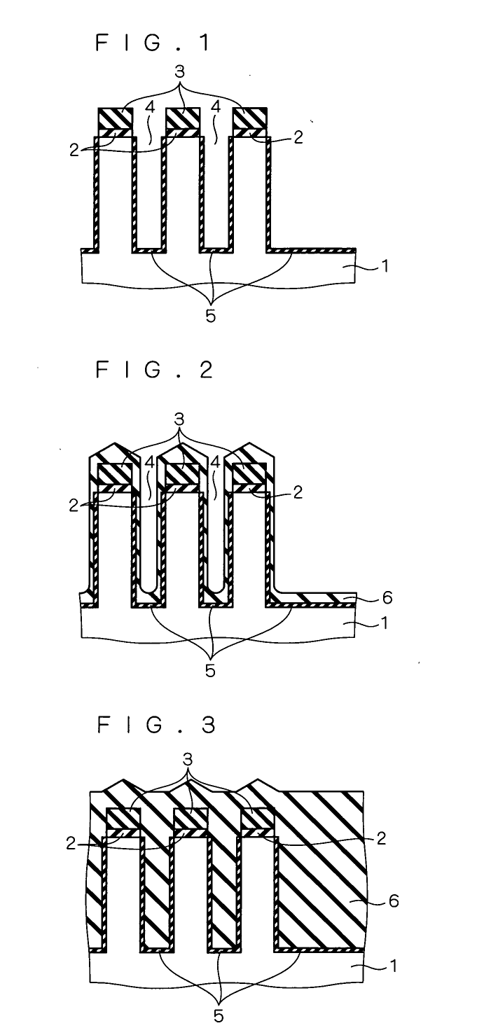

By the steps to the above, as shown in FIG. 1, a plurality of trenches (it can be grasped as a depressed portion) 4 of a predetermined pattern are formed in the front surface of silicon substrate 1. Here, the trench 4 concerned is a trench for element isolation. The depth of the trench 4 concerned are about 300 nm-500 nm, and the width is 100 nm or less.

Next, as shown in FIG. 1, oxide film 5 is formed in the bottom face and inner wall of trench 4 which were formed. Here, in order to remove the damage in the case of dry etching, the oxide film 5 concerned is formed.

Next, silicon substrate 1 in which the trenches 4 concerned were formed is installed in a high-density-plasma CVD (HDP-CVD) apparatus.

And the silicon substrate 1 concerned is heated using a plasma phenomenon to more than or equal to 400° C.

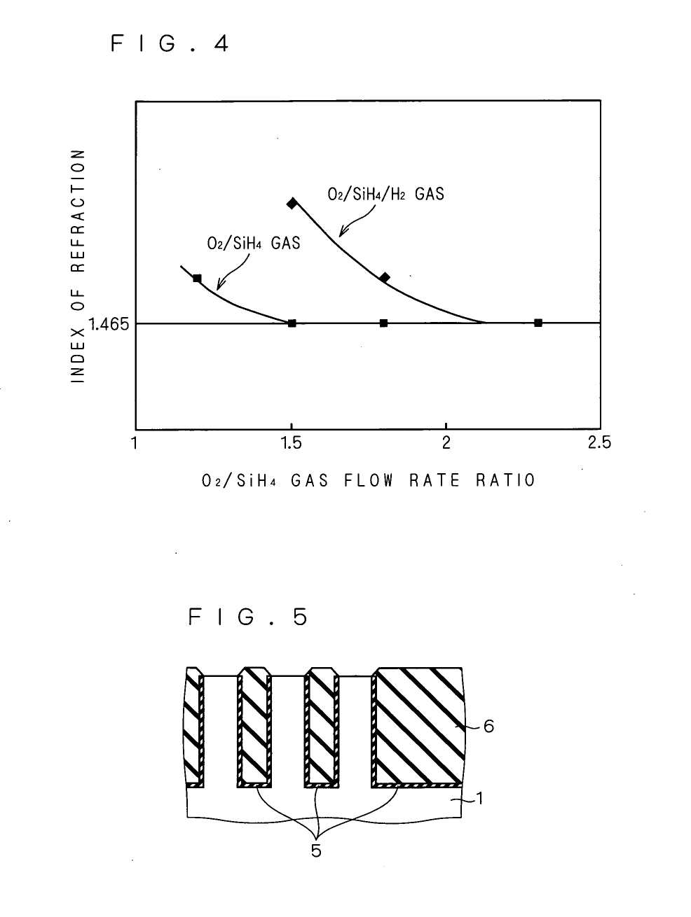

Silicon oxide film 6 is formed in trench 4 according to the following conditions after the heat-treatment concerned next. The state of the silicon oxide film 6 formation concerned is shown in FIGS. 2 and 3.

Here, FIG. 2 is a drawing showing the state in the middle of formation of silicon oxide film 6. FIG. 3 is a drawing showing the state that formation of silicon oxide film 6 was completed. As shown in FIG. 3, silicon oxide film 6 is filled up in trench 4, and is further formed on silicon substrate 1.

Formation of the silicon oxide film 6 concerned is carried out performing the deposition process and the sputtering process simultaneously.

Formation of silicon oxide film 6 is performed under the conditions that source RF power is about 4000-5000 W, bias RF power is about 2000-4000 W, and a flow rate ratio (=O₂/SiH₄) is less than 1.5, using O₂/SiH₄ mixed gas. That is, silicon oxide film 6 is formed in the inside of the trench in the state of silicon-richness.

Formation of silicon oxide film 6 can also be carried out under the conditions that the source RF power is about 4000-5000 W, bias RF power is about 2000-4000 W, introduction of hydrogen (H₂) gas (using O₂/SiH₄/H₂ mixed gas), and a flow rate ratio (=O₂/SiH₄) is less than 2.0.

That is, on both conditions, silicon oxide film 6 is formed in the inside of the trench in the state of silicon-richness.

Silicon oxide film 6 formed by the step concerned is a silicon oxide film of silicon-richness as above-mentioned. The refractive index of the silicon oxide film 6 concerned exceeds 1.465. Here, the measurement wavelength of the refractive index is about 633 nm. In the stoichiometric composition of the silicon oxide film 6 concerned, oxygen is missing as compared with a stable state. In other words, in the stoichiometric composition of the silicon oxide film 6 concerned, silicon is superfluous as compared with a stable state.

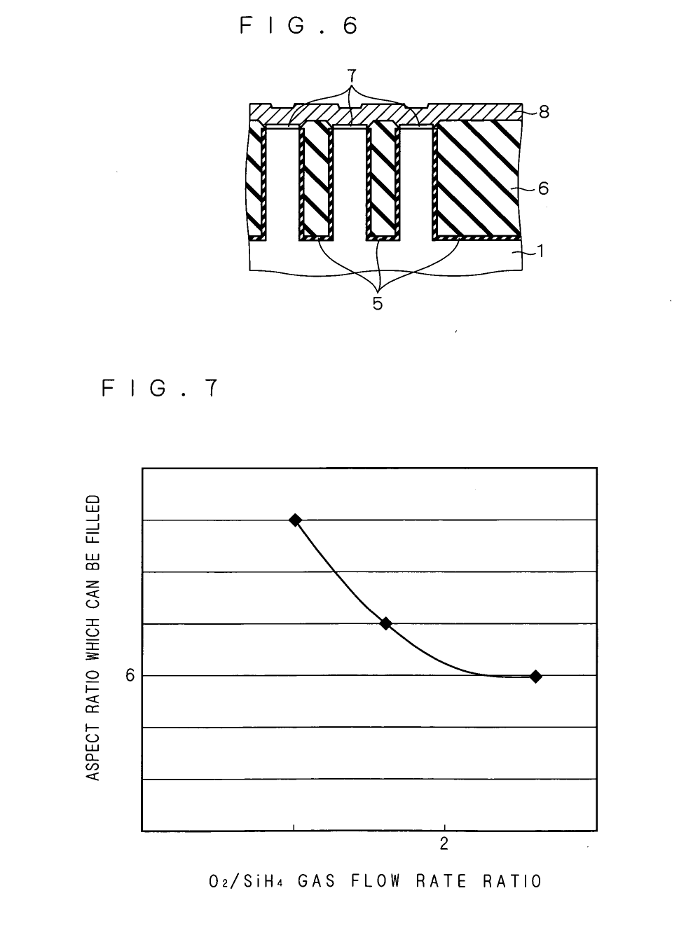

The experimental result which shows the relation between a flow rate ratio (=O₂/SiH₄), and the refractive index of silicon oxide film 6 formed is shown in FIG. 4.

As shown in FIG. 4, when not introducing H₂ gas and a flow rate ratio (=O₂/SiH₄) becomes less than 1.5, the refractive index of silicon oxide film 6 will exceed 1.465 (that is, it will be in the state of silicon-richness). When H₂ gas is introduced and a flow rate ratio (=O₂/SiH₄) becomes less than 2.0, the refractive index of silicon oxide film 6 will exceed 1.465 surely (that is, it will be in the state of silicon-richness).

Next, CMP (Chemical and Mechanical Polishing) is given to the upper surface of the silicon substrate 1 concerned for flattening of the upper surface of silicon substrate 1. The CMP treatment concerned removes silicon oxide film 6 on silicon substrate 1. Then, oxide film 2 and silicon nitride film 3 are removed by wet etching.

Therefore, as shown in FIG. 5, trench 4, and oxide film 5 and silicon oxide film 6 currently formed only in the trench 4 concerned exist in silicon substrate 1. That is, a plurality of STI of a predetermined pattern are formed in the front surface of silicon substrate 1.

Then, as shown in FIG. 6, gate insulating film 7 and gate electrode 8 are formed on silicon substrate 1.

As mentioned above, in the manufacturing method of the semiconductor device concerning this embodiment, silicon oxide film 6 is formed in trench (depressed portion) 4 according to the conditions of less than a predetermined flow rate ratio (O₂/SiH₄=1.5 or 2).

Inventors discovered that the filling property of silicon oxide film 6 improved by making a flow rate ratio (=O₂/SiH₄) into less than 1.5, when H₂ gas was not introduced, as mentioned above. When H₂ gas was introduced, it was discovered that the filling property of silicon oxide film 6 improved by making a flow rate ratio (=O₂/SiH₄) into less than 2.0.

FIG. 7 is an example of the experimental result which shows the fact concerned. In FIG. 7, a vertical axis is an aspect ratio of trench 4 (arbitrary unit), and a horizontal axis is a flow rate ratio (=O₂/SiH₄). FIG. 7 is experimental data at the time of introducing H₂ gas.

The aspect ratio of trench 4 which can fill silicon oxide film 6 without void improves by leaps and bounds as a flow rate ratio (=O₂/SiH₄) decreases from a predetermined value (=less than 2) as shown in FIG. 7.

Therefore, silicon oxide film 6 without void can be formed in trench 4 (depressed portion), without increasing RF bias of a plasma CVD device by adopting the method concerned in this embodiment.

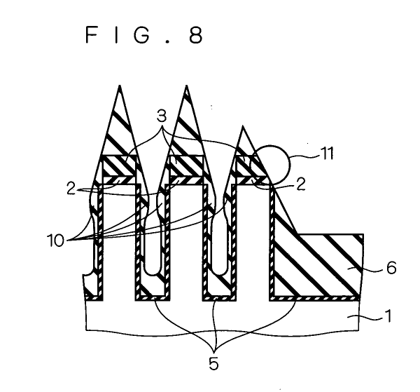

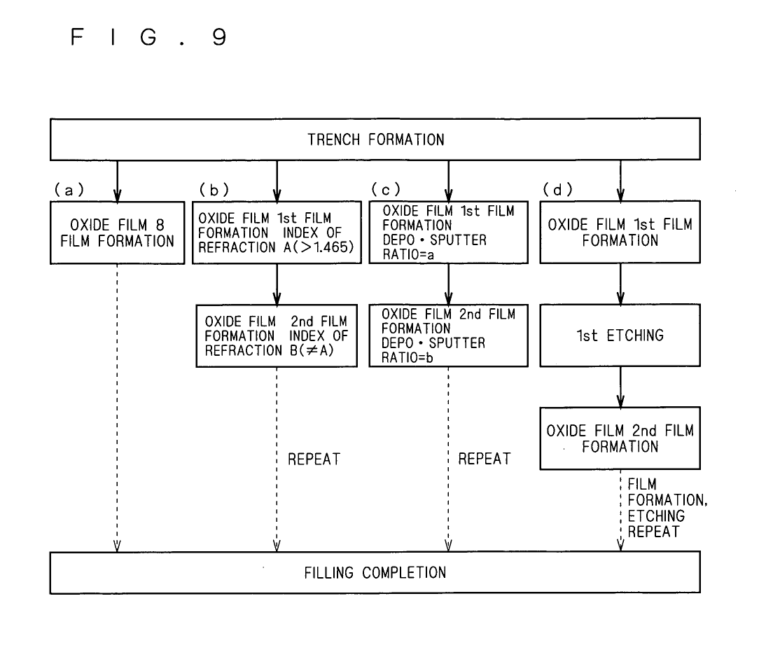

Thus, since the need of increasing RF bias is lost, the re-deposition (reference 10 of FIG. 8) near the opening of trench 4 can be prevented. The shoulder cutting (reference 11 of FIG. 8) in the upper part of trench 4 can also be prevented.

Silicon oxide film 6 is formed in the manufacturing method of the semiconductor device concerning this embodiment, suppressing the generation of void. That is, there is no need of processing for a long time for extinguishing the void concerned after forming an insulating film in the inside of a trench like the manufacturing method concerning Patent Reference 1, generating void.

Therefore, the technology concerning this embodiment is more practical and more economical than invention concerning Patent Reference 1.

It is very difficult to extinguish the void formed once by a back process as mentioned above. However, silicon oxide film 6 is formed in this embodiment, preventing the generation of void as above-mentioned. That is, when formation of silicon oxide film 6 to trench 4 is completed, void is not generated in the silicon oxide film 6 concerned.

By the above, STI in which void does not exist can be more surely formed, for example rather than invention concerning Patent Reference 1 by adopting the manufacturing method concerning this embodiment.

When the manufacturing method of the semiconductor device concerning this embodiment is adopted, silicon oxide film 6 formed will be in the state of silicon-richness as above-mentioned (In other words, the more a flow rate ratio (=O₂/SiH₄) will decrease, the more the refractive index of silicon oxide film 6 increases from 1.465. Refer to FIG. 4.). When seeing from another viewpoint in the state of the silicon-richness concerned, it can be said that as compared with stoichiometric composition, oxygen is missing, or silicon is superfluous as compared with stoichiometric composition.

Fluorine may be made to contain in the raw gas in the above-mentioned silicon oxide film 6 formation (that is, in the midst of forming silicon oxide film 6 in trench 4, performing a deposition process and a sputtering process simultaneously). For example, SiF₄ and NF₃ may be added into raw gas.

Thus, simultaneously with film formation of silicon oxide film 6, the etching process by fluorine radicals is also performed by making fluorine contain. Therefore, the filling of silicon oxide film 6 into trench 4 can be further improved by combining the above-mentioned decrease conditions of a flow rate ratio (=O₂/SiH₄), and inclusion of the fluorine to the inside of raw gas.

When fluorine is made to contain in raw gas, in silicon oxide film 6 formed, fluorine is also included a little.

As mentioned above, when NF₃ is added into raw gas, in silicon oxide film 6 formed, nitrogen is also included a little besides fluorine.

Hydrogen and helium may be made to contain in the raw gas in silicon oxide film 6 formation (that is, in the midst of forming silicon oxide film 6 in trench 4, performing a deposition process and a sputtering process simultaneously).

Thus, by making hydrogen or helium contain, a sputtering process of the overhang formed near the opening of trench 4 is performed by hydrogen or helium concerned with light mass. Therefore, re-deposition of the film to which sputtering was done is done to the upper part in trench 4. That is, the re-deposition of the film to which sputtering was done in near the opening (concretely, directly under the overhang) of trench 4 can be suppressed more.

Here, when hydrogen is used, the flow rate ratio (=O₂/SiH₄) is made into less than 2.0.

Argon may be made to contain in the raw gas in silicon oxide film 6 formation (that is, in the midst of forming silicon oxide film 6 in trench 4, performing a deposition process and a sputtering process simultaneously).

Thus, silicon oxide film 6 can be formed, thinking a sputtering process as important more by making argon contain.

Argon, hydrogen, or helium can be made to contain in raw gas by adopting O₂/SiH₄/He mixed gas, O₂/SiH₄/He/H₂ mixed gas, O₂/SiH₄/Ar mixed gas, O₂/SiH₄/He/Ar mixed gas, O₂/SiH₄/Ar/H₂ mixed gas, or O₂/SiH₄/He/Ar/H₂ mixed gas as raw gas.

It can also have the above-mentioned etching effect by including fluorine (for example, SiF₄, NF₃, etc.) in the mixed gas on which exemplification listing mentioned above was done.

### Embodiment 2

In Embodiment 1, reference was made about the step which forms silicon oxide film 6 in trench 4 by one step. However, an oxide film (oxide film which includes the silicon oxide film region of structure of which Embodiment 1 explained in part at least) may be formed in trench 4 by giving a plurality of film formation steps from which conditions differ.

This embodiment explains the case where an oxide film is formed in trench 4 by giving a plurality of film formation steps concerned from which conditions differ.

FIG. 9 is a process flow chart showing the variation of the semiconductor manufacturing device (concretely formation method of an oxide film) concerning this embodiment.

The step pattern (a) of FIG. 9 is a case where an oxide film (silicon oxide film 6) is formed in trench 4 by one step (on one film formation condition), as Embodiment 1 explained. Here, as Embodiment 1 explained, the flow rate ratio at the time of a film formation step (=O₂/SiH₄) is set to less than the predetermined value (1.5 or 2). Formation of the oxide film concerned is carried out performing a deposition process and a sputtering process simultaneously.

The step pattern (b) of FIG. 9 is a step which forms an oxide film (oxide film which includes the silicon oxide film region of the structure on which Embodiment 1 explained in part at least), performing a deposition process and a sputtering process simultaneously. A step pattern (b) is a case where an oxide film is formed in trench 4 changing the value of the flow rate ratio at the time of the film formation concerned (=O₂/SiH₄).

In a step pattern (b), the flow rate ratio (=O₂/SiH₄) needs to be less than 1.5 (when O₂/SiH₄/H₂ mixed gas is used, it is less than 2.0) at the first step at least. This is because improvement in filling property is required most in the initial stage of filling.

Therefore, in a step pattern (b), only the first filling (filling from bottom of trench 4 to predetermined depth) step may be performed on the condition whose flow rate ratio (=O₂/SiH₄) is less than 1.5 (it is less than 2.0 when O₂/SiH₄/H₂ mixed gas is used), and the subsequent filling step may be performed on the condition whose flow rate ratio (=O₂/SiH₄) is 1.5 or more (it is 2.0 or more when O₂/SiH₄/H₂ mixed gas is used).

In a step pattern (b), the steps from the first filling to the filling of intermediate multiple times (filling from bottom of trench 4 to predetermined depth) may be carried out on the conditions whose flow rate ratios (=O₂/SiH₄) are less than 1.5 (it is less than 2.0 when O₂/SiH₄/H₂ mixed gas is used), and the filling step after the filling step concerned of intermediate multiple times may be performed on the conditions whose flow rate ratios (=O₂/SiH₄) are 1.5 or more (it is 2.0 or more when O₂/SiH₄/H₂ mixed gas is used).

In the above any case, it is desirable to make a flow rate ratio (=O₂/SiH₄) increase as the number of times of a filling step increases (that is, as it approaches the opening from the bottom of trench (depressed portion) 4).

It is because the oxide film concerned can be brought close to stoichiometry (composition in which the stoichiometric composition is stable) (in other words, the refractive index of an oxide film can be brought close to 1.465 (or it is made 1.465)) as it takes toward the upper layer from the bottom of an oxide film (oxide film which includes the silicon oxide film region of the structure on which Embodiment 1 explained in part at least) by doing like this.

The oxide film formed as a result of the step pattern (b) concerned includes the silicon oxide film region of silicon-richness (or it exceeds refractive index 1.465, or oxygen is missing as compared with stoichiometric composition, or silicon is superfluous as compared with stoichiometric composition) in part at least as above-mentioned. Especially the silicon oxide film region of the structure on which the Embodiment 1 concerned explained is formed in the bottom of trench (depressed portion) 4.

In FIG. 9, only two film formation steps of a step pattern (b) are illustrated. However, it is natural that the number of the steps is beyond this.

The step pattern (c) of FIG. 9 is a step which forms an oxide film (oxide film which includes the silicon oxide film region of the structure on which Embodiment 1 explained in part at least), performing a deposition process and a sputtering process simultaneously, and is a case where the oxide film concerned is formed in trench 4, changing the ratio of a sputtering rate to a deposition rate.

Here, a flow rate ratio (=O₂/SiH₄) may be changed in the step pattern (c) concerned (in other words, it may be fixed at less than a predetermined flow rate ratio (2 or 1.5)). However, to change a flow rate ratio (=O₂/SiH₄), in one of film formation steps, it is necessary to include the step whose flow rate ratio (=O₂/SiH₄) is less than 1.5 (it is less than 2.0 when O₂/SiH₄/H₂ mixed gas is used) between the film formation steps of multiple times.

To change a flow rate ratio (=O₂/SiH₄) especially, the flow rate ratio (=O₂/SiH₄) of the first step at least needs to be less than 1.5 (when O₂/SiH₄/H₂ mixed gas is used, it is less than 2.0). This is because improvement in filling property is required most in the initial stage of filling.

The region of the oxide film formed by the flow rate ratio (=O₂/SiH₄) of the conditions concerned is a silicon oxide film region of silicon-richness (or it exceeds refractive index 1.465, or oxygen is missing as compared with stoichiometric composition, or silicon is superfluous as compared with stoichiometric composition) as above-mentioned (especially the silicon oxide film region of the structure on which the Embodiment 1 concerned explained is formed in the bottom of trench (depressed portion) 4).

By a step pattern (c), as it approaches the opening from the bottom of trench (depressed portion) 4 concretely, the ratio of a sputtering rate to a deposition rate is decreased.

This is because it is necessary to think sputtering near the opening of trench 4 as important from a viewpoint of the opening occlusion in a film formation initial stage, and it is necessary to think a deposition process as important from a viewpoint of the improvement in a deposition rate on the other hand when the above-mentioned oxide film is formed in trench 4 to a certain amount of depth, in film formation of the above-mentioned oxide film.

In FIG. 9, only two film formation steps of a step pattern (c) are illustrated. However, it is natural that the number of steps is beyond this.

The step pattern (d) of FIG. 9 is a step which forms an oxide film (oxide film which includes the silicon oxide film region of the structure on which Embodiment 1 explained in part at least) while performing a deposition process and a sputtering process simultaneously, and is a case where an etching process step is separately performed in the middle of film formation of the oxide film concerned into trench 4.

Here, a flow rate ratio (=O₂/SiH₄) may be changed in the step pattern (d) concerned (in other words, it may be fixed at less than a predetermined flow rate ratio (1.5 or 2)). However, to change a flow rate ratio (=O₂/SiH₄), in one of film formation steps, it is necessary to include the step whose flow rate ratio (=O₂/SiH₄) is less than 1.5 (it is less than 2.0 when O₂/SiH₄/H₂ mixed gas is used) between the film formation steps of multiple times.

To change a flow rate ratio (=O₂/SiH₄) especially, the flow rate ratio (=O₂/SiH₄) of the first step at least needs to be less than 1.5 (when O₂/SiH₄/H₂ mixed gas is used, it is less than 2.0). This is because improvement in filling property is required most in the initial stage of filling.

The region of the oxide film formed by the flow rate ratio (=O₂/SiH₄) of the conditions concerned is a silicon oxide film region of silicon-richness (or it exceeds refractive index 1.465, or oxygen is missing as compared with stoichiometric composition, or silicon is superfluous as compared with stoichiometric composition) as above-mentioned (especially the silicon oxide film region of the structure on which the Embodiment 1 concerned explained is formed in the bottom of trench (depressed portion) 4).

As shown in FIG. 9, after forming the above-mentioned oxide film to the depth in the middle of trench (depressed portion) 4, the film formation process concerned is interrupted for a step pattern (d), and an etching process is separately performed independently.

The etching process concerned is concretely performed to near the opening of trench 4. And, after performing the etching process concerned for a predetermined time, the film formation process of the above-mentioned oxide film to trench 4 is resumed. Thus, by a step pattern (d), the above-mentioned oxide film is formed in trench 4 by repeating and performing film formation and etching of an oxide film.

As mentioned above, by performing separately the etching process to near the opening of trench 4 in the middle of film formation of the oxide film, occlusion near the opening concerned can be suppressed more before the oxide film is thoroughly formed in trench 4.

In the above, reference was made by the step pattern (d) about the case where film formation and etching of the oxide film are performed by turns one by one.

However, for example, after performing the film formation process of multiple times changing the flow rate ratio (=O₂/SiH₄), the above-mentioned etching process may be performed separately and the film formation process may be again resumed after the etching process concerned like the step pattern (b).

Moreover, for example, after performing the film formation process of multiple times changing the sputtering process ratio to a deposition process, the above-mentioned etching process may be performed separately, and the film formation process may be again resumed after the etching process concerned like the step pattern (c).

At FIG. 9, only the film formation step of two times and 1 time of the etching step performed between them are illustrated by the step pattern (d).

However, it is natural that the number of times of a film formation step and the number of times of an etching step may be beyond this.

As mentioned above, the oxide film near the upper part of trench 4 can be made into stoichiometry (composition in which the stoichiometric composition is stable) (or it can be brought close to stoichiometry more) by adopting the step pattern (b).

Therefore, even if a gate electrode is formed on STI which includes the oxide film of the above-mentioned structure as Embodiment 3 may explain, leak of the gate current into the oxide film concerned can be suppressed. Also when removing the oxide film on silicon substrate 1 etc. and performing CMP treatment for flattening of the upper surface of the silicon substrate 1 concerned, the CMP treatment concerned can be performed according to the CMP conditions of existing (silicon oxide film of stoichiometry). That is, the changing CMP conditions can be prevented.

By adopting the step pattern (c), for example, as it approaches the opening from the bottom of trench 4, it can shift to the process condition of deposit serious consideration from the process condition of sputtering serious consideration. Therefore, it can fill up the oxide film of the above-mentioned structure which does not include void in trench 4 more efficiently.

The occlusion near the opening concerned before the oxide film of the above-mentioned structure is thoroughly formed in trench 4 can be suppressed more by adopting the step pattern (d).

When performing a film formation process dividing into multiple times, to a predetermined depth from the bottom of trench 4 at least, the oxide film of the above-mentioned structure is formed to the middle on the conditions whose flow rate ratios (=O₂/SiH₄) are less than 1.5 (it is less than 2.0 when O₂/SiH₄/H₂ mixed gas is used).

That is, in the state where the aspect ratio of trench 4 is the highest, the flow rate ratio of the above-mentioned conditions is adopted. Therefore, as Embodiment 1 explained, in the phase where the aspect ratio concerned is the highest, the oxide film concerned can be formed in trench 4 on the best condition of filling property.

### Embodiment 3

As each above-mentioned embodiment explained, suppose that the oxide film was formed in trench 4 only on the condition whose flow rate ratio (=O₂/SiH₄) is less than 1.5 (it is less than 2.0 when O₂/SiH₄/H₂ mixed gas is used). Then, the oxide film in trench 4 (that is, STI) and the oxide film on silicon substrate 1 turn into silicon oxide film 6 of the structure on which Embodiment 1 explained as above-mentioned.

Suppose that gate electrode 8 was formed on silicon oxide film 6 which has the structure concerned as shown in FIG. 6. Then, there is a possibility that leakage current may flow into STI from the gate electrode 8 concerned, at the time of operation of a semiconductor device.

To perform CMP treatment to silicon oxide film 6 which has the structure explained by above-mentioned Embodiment 1, it is necessary to change CMP conditions according to the structure (composition) of silicon oxide film 6. This is because unpolished parts occur on silicon nitride film 3 originating in the difference of a polishing rate, when silicon oxide film 6 of the structure on which Embodiment 1 explained is polished on the CMP conditions to the silicon oxide film which is stoichiometry (stoichiometric composition is stable).

When changing CMP conditions, unless the CMP conditions concerned are set up correctly, CMP treatment cannot be performed normally. That is, alteration of the CMP conditions concerned is very difficult.

The embodiment created in view of the above thing is this embodiment. Hereafter, the manufacturing method of the semiconductor device concerning this embodiment is explained.

By giving the forming step of silicon oxide film 6 explained by Embodiment 1, as shown in FIG. 3, silicon oxide film 6 is formed on silicon substrate 1 so that it may fill up trench 4.

Here, as Embodiment 1 explained, formation of silicon oxide film 6 is performed on the condition whose flow rate ratio (=O₂/SiH₄) is less than 1.5, when hydrogen is not included. When hydrogen is included (O₂/SiH₄/H₂ mixed gas is used), silicon oxide film 6 is formed on the condition whose flow rate ratio (=O₂/SiH₄) is less than 2.0.

As raw gas, like Embodiment 1, O₂/SiH₄/He mixed gas, O₂/SiH₄/He/H₂ mixed gas, O₂/SiH₄/Ar mixed gas, O₂/SiH₄/He/Ar mixed gas, O₂/SiH₄/Ar/H₂ mixed gas, O₂/SiH₄/He/Ar/H₂ mixed gas, the mixed gas which included fluorine (for example, SiF₄, NF₃, etc.) in the mixed gas which is done above-mentioned exemplification listing, etc. are employable.

The effect at the time of adopting each mixed gas is as Embodiment 1 having explained.

Next, oxygen plasma treatment is performed to silicon substrate 1 on which the silicon oxide film 6 concerned was formed in the plasma CVD device in which the above-mentioned silicon oxide film 6 was formed (film formation). Here, the oxygen plasma treatment concerned is carried out on the conditions that source RF power is about 2000-4000 W and oxygen (O₂) flow rate is about 200 sccm. The oxygen plasma treatment concerned is performed using oxygen ions or oxygen radicals.

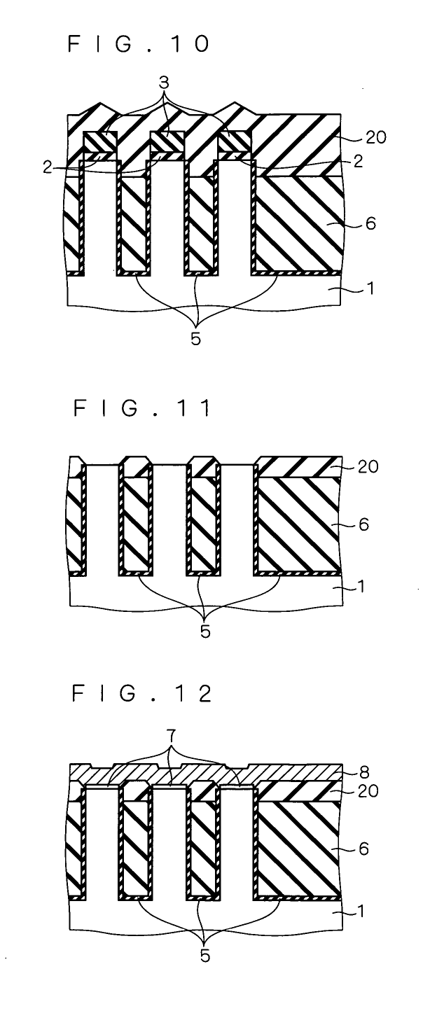

By the oxygen plasma treatment concerned, as shown in FIG. 10, oxidizing zone 20 can be formed in the front surface of silicon oxide film 6.

The oxidizing zone 20 concerned is formed till the region where CMP treatment is performed, desirably till near the upper part of STI (near the opening of trench 4).

CMP treatment is performed after the oxygen plasma treatment concerned to silicon oxide film 6 in which oxidizing zone 20 is formed. By this, as shown in FIG. 11, flattening of the upper surface of silicon substrate 1 is done, and a plurality of STI are completed in the front surface of the silicon substrate 1 concerned. Here, oxide film 2 and silicon nitride film 3 are removed by the wet etching process after the CMP treatment concerned.

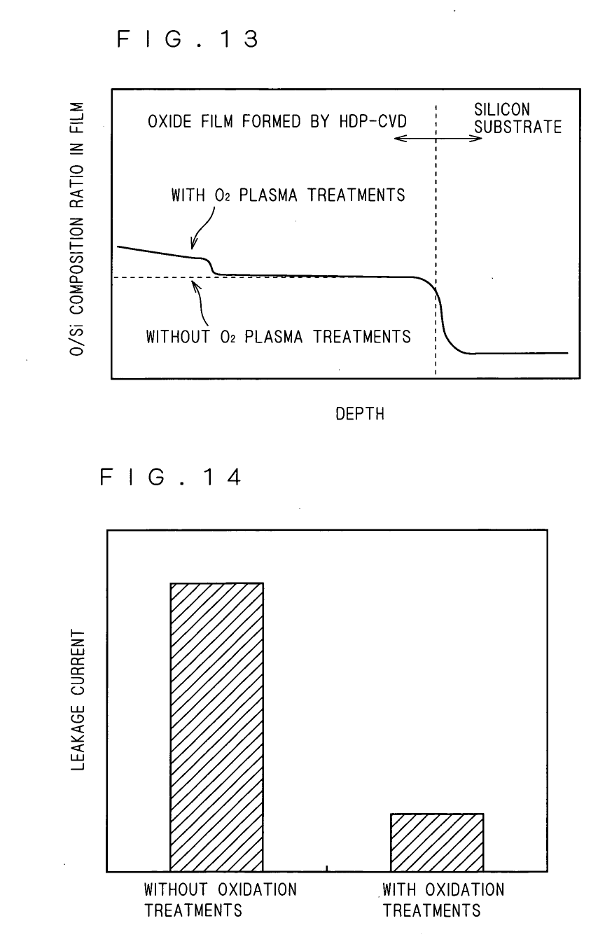

As shown in FIG. 12 after the above-mentioned process to oxide film 2 concerned and the silicon nitride film 3 concerned, gate insulating film 7 and gate electrode 8 are formed on silicon substrate 1.

As mentioned above, in this embodiment, oxygen plasma treatment has been performed to silicon substrate 1. Therefore, in near the front surface of silicon oxide film 6 at least, the composition ratio of oxygen to silicon goes up as compared with the condition before the plasma oxidation process concerned is performed. That is, oxidizing zone 20 in which the ratio of oxygen rose is formed in silicon oxide film 6.

Here, FIG. 13 is an example of experimental data which shows a state that the composition ratio of oxygen to silicon in silicon oxide film 6 goes up by performing oxygen plasma treatment. In FIG. 13, the horizontal axis is a depth and the vertical axis is O/Si composition ratio. Since FIG. 13 is used by qualitative explanation, the unit is omitted. In FIG. 13, the left end of the horizontal axis is equivalent to the maximum front surface.

As shown in FIG. 13, by performing the above-mentioned oxygen plasma treatment after forming silicon oxide film 6 by the method of the description in Embodiment 1, the composition ratio of the oxygen to silicon rises at least in near the front surface of silicon oxide film 6. A dotted line is data in the case where oxygen plasma treatment is not performed.

The rise of the composition ratio of the oxygen to the above-mentioned silicon shows that oxidizing zone 20 formed in silicon oxide film 6 is approaching stoichiometry (composition in which the stoichiometric composition is stable) (or it is stoichiometry).

Since a stoichiometry (or having composition near this) STI (oxidizing zone 20) is formed at least in near the front surface in this way, even if gate electrode 8 is formed on the STI concerned, it can be suppressed that leakage current flows into STI from the gate electrode 8 concerned at the time of operation of a semiconductor device. This is confirmed also from the experiment.

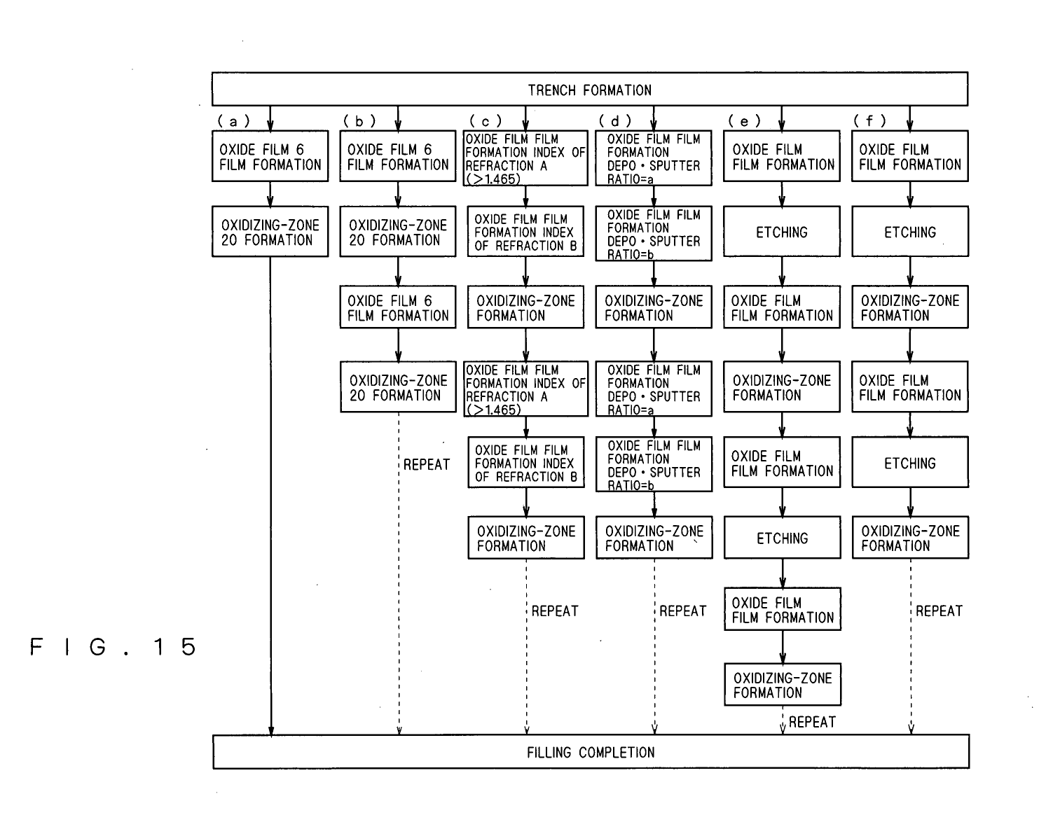

FIG. 14 is the experimental data in which the difference in the above-mentioned leakage current generation between the case where oxygen plasma treatment of this embodiment is performed, and the case where the oxygen plasma treatment concerned is not performed after silicon oxide film 6 is formed on condition of less than a predetermined flow rate ratio (=O₂/SiH₄=1.5 or 2) is shown. In FIG. 14, the vertical axis is leakage current (arbitrary unit). FIG. 14 is a drawing showing the relative comparison of leakage current.

As shown in FIG. 14, in the case where oxygen plasma treatment described in this embodiment is performed, the amount of leakage current which flows into STI (silicon oxide film 6 which has oxidizing zone 20) from gate electrode 8 formed later is decreasing substantially.

As the above-mentioned description, at least the composition of the upper part (that is, composition of the oxidizing zone 20 concerned) of STI (silicon oxide film 6 which has oxidizing zone 20) becomes stoichiometry (or composition near this). Therefore, the CMP conditions to the silicon oxide film of stoichiometry currently carried out from the former are maintainable. That is, CMP for silicon oxide film 6 which has the oxide film 20 concerned can be performed normally without need of changing CMP conditions.

It is natural that silicon oxide film 6 formed by the manufacturing method concerning this embodiment has the effect explained by Embodiment 1.

As each above-mentioned effect shows, in order to acquire each effect concerned, it is necessary to do plasma oxidation of the silicon oxide film 6 near the opening of trench (depressed portion) 4 by the oxygen plasma treatment concerning this embodiment at least. That is, it is necessary to form oxidizing zone 20 in silicon oxide film 6 near the opening of trench (depressed portion) 4 at least.

Oxygen plasma treatment concerning this embodiment is performed in the same apparatus as the plasma apparatus which forms silicon oxide film 6. Therefore, the manufacturing process is simplified.

Since oxygen plasma treatment should just be carried out using the gas in which oxygen was included at least, there is no need of limiting to oxygen gas.

### Embodiment 4

In Embodiment 3, reference was made about the case where oxygen plasma treatment is performed after forming silicon oxide film 6 with the manufacturing method concerning Embodiment 1. This embodiment explains the case where oxygen plasma treatment is performed after forming an oxide film (oxide film which includes the silicon oxide film region of the structure on which Embodiment 1 explained in part at least) with each manufacturing method concerning Embodiment 2 (or it includes also in the middle of film formation).

FIG. 15 is a process flow chart showing the variation of the semiconductor manufacturing device (concretely the formation method of an oxide film and the oxidation method of the oxide film concerned) concerning this embodiment.

The step pattern (a) of FIG. 15 is a case where silicon oxide film 6 is formed in trench 4 in one step (on one film formation condition), and oxygen plasma treatment is performed to the silicon oxide film 6 concerned after that as Embodiment 3 explained. Here, formation of silicon oxide film 6 is performed, performing the deposition process and the sputtering process simultaneously.

The step pattern (b) of FIG. 15 is a step which forms an oxide film (silicon oxide film 6) by the method of a description in Embodiment 1 while performing the deposition process and the sputtering process simultaneously.

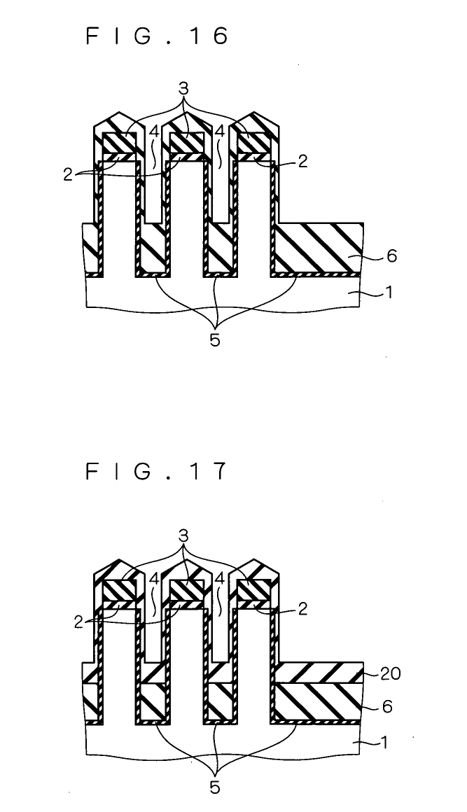

A step pattern (b) is a case where the oxide film in the middle of film formation is oxidized (that is, oxidizing zone 20 is formed) by the oxygen plasma treatment which was explained in Embodiment 3, interrupting film formation of the oxide film, as shown in FIGS. 16 to 18. The number of times of film formation of an oxide film, and the number of times of oxidation (that is, formation of an oxidizing zone) of an oxide film in the middle of formation do not have to be limited to the number of times described to the step pattern (b) of the drawing.

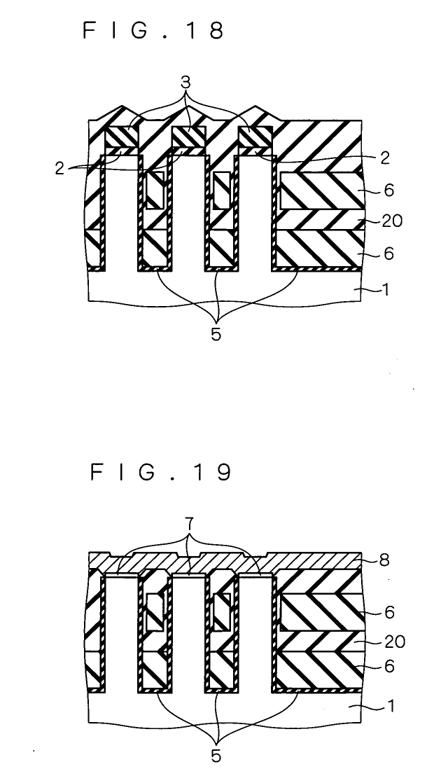

Incidentally, in the structure shown in FIG. 18, CMP is given to the upper surface of the silicon substrate 1 concerned for flattening of the upper surface of silicon substrate 1. The CMP concerned removes oxidizing zone 20 on silicon substrate 1. Then, oxide film 2 and silicon nitride film 3 are removed by wet etching process. Then, as shown in FIG. 19, gate insulating film 7 and gate electrode 8 are formed on silicon substrate 1.

Returning the story, the step pattern (c) of FIG. 15 is a case where the oxygen plasma treatment explained in Embodiment 3 to the oxide film in the middle of film formation and after the completion of film formation of oxide film concerned (oxide film which includes silicon oxide film region of the structure on which Embodiment 1 explained in part at least) is added in the step pattern (b) of FIG. 9 in which the value of the flow rate ratio (=O₂/SiH₄) was changed.

As for the steps of the film formation of an insulating film and the oxidation of the insulating film concerned of the step pattern (c) of FIG. 15, there is no meaning of limiting to the number of times shown in FIG. 19. The time to introduce an oxidation step can also be arbitrarily chosen into the film formation step.

The step pattern (d) of FIG. 15 is a case where the oxygen plasma treatment explained in Embodiment 3 is added in the middle of film formation of the oxide film and after the completion of film formation of the oxide film, in the step pattern (c) of FIG. 9 in which the ratio of the sputtering rate to the deposition rate was changed.

As for the steps of film formation and oxidation of the step pattern (d) of FIG. 15, there is no meaning of limiting to the number of times currently illustrated. The time to introduce an oxidation step can also be arbitrarily chosen into a film formation step.

Step pattern (e) or (D) of FIG. 15 is a case where the oxygen plasma treatment explained in Embodiment 3 is added in the middle of film formation of an oxide film and after the completion of film formation of an oxide film, in the step pattern (d) of the FIG. 9 which gives an etching step in the middle of film formation of an oxide film separately. As shown in FIG. 15, the timing to which an oxidation step and an etching step are given is different with the step pattern (e) and the step pattern (I). For example, in the step pattern (f) of FIG. 15, the oxidation step is given after the etching step.

As for the film formation, oxidation, and etching steps of step pattern (e) and (f) of FIG. 15, there is no meaning of limiting to the number of times currently illustrated. The time to introduce an oxidation step and an etching step can also be arbitrarily chosen into a film formation step.

In each step pattern shown in FIG. 15, an oxidizing zone is formed at the inside of an oxide film, and in the front surface of an oxide film by performing oxygen plasma treatment. Here, composition of the oxidizing zone concerned is stoichiometry (silicon oxide film whose stoichiometric composition is stable), or composition near the stoichiometry concerned. The silicon oxide film region of the structure on which Embodiment 1 explained is included in the oxide film in part at least.

As mentioned above, in the manufacturing method concerning this embodiment, not only near the front surface of the oxide film, but also in the inside of the oxide film concerned, the silicon oxide film of stoichiometry (or composition near this) is formed.

Therefore, the generation of leakage current which was explained in Embodiment 3 can be suppressed more. The insulation in the inside of the oxide film (STI) concerned improves as compared with the case where the inside of the oxide film concerned is not oxidized.

In the manufacturing method concerning this embodiment, it is natural that the effect explained in Embodiment 2 is obtained.

When oxygen plasma treatment is performed to the last like Embodiment 3 after forming an oxide film thoroughly in trench 4, of course, the same effect as the effect explained in Embodiment 3 is also obtained.

In each above-mentioned embodiment, reference was made about the case where the manufacturing method concerning each embodiment is applied in the case of formation of STI. However, when the depressed portion is formed in the foundation and an oxide film is filled in the depressed portion concerned, for example like the interlayer insulation films between the gate electrodes of a transistor, between the upper wirings, etc., the manufacturing method concerning each embodiment can be applied. In particular, when the aspect ratio of the depressed portion is high, application of the present invention becomes more effective.

In each above-mentioned embodiment, reference was made about the case where a HDP-CVD apparatus is used when forming the oxide film which includes the silicon oxide film region of the structure on which Embodiment 1 explained in part at least in trench (depressed portion) 4. However, the oxide film which includes the silicon oxide film region of the structure on which Embodiment 1 explained in part at least can also be formed in trench (depressed portion) 4 using a plasma CVD device at large.

Above, the oxide film which includes the silicon oxide film region of the structure on which Embodiment 1 explained in part at least is formed using a gas system including O₂ and SiH₄. However, even if a gas system including O₂ and TEOS, for example, is used, the oxide film concerned can be formed.

Above, reference was made about the case where a semiconductor device has oxide film filled structure described in each embodiment, and the manufacturing method of a semiconductor device which has the oxide film filling method described in each embodiment as a part of the step.

However, the oxide film filled structure and the method of filling an oxide film which are concerned in the present invention are applicable also in electron devices, such as a flat-panel display or MEMS (Micro Electron Mechanical System), for example, also except the field regarding the semiconductor device.

That is, it is natural that it is applicable to other apparatus which have the filled structure which fills an oxide film at the depressed portion currently formed in the foundation, and to the manufacturing method of other apparatus which has the method to fill an oxide film concerned as a part of the step.

What is claimed is:

1. An oxide film filled structure, comprising:
a foundation having a depressed portion; and
an oxide film which is formed in the depressed portion and includes silicon and oxygen;
wherein the oxide film includes a silicon oxide film region of silicon-richness in part at least.

2. An oxide film filled structure, comprising:
a foundation having a depressed portion; and
an oxide film which is formed in the depressed portion and includes silicon and oxygen;
wherein the oxide film includes a silicon oxide film region where an index of refraction exceeds 1.465 in part at least.

3. An oxide film filled structure, comprising:
a foundation having a depressed portion; and
an oxide film which is formed in the depressed portion and includes silicon and oxygen;
wherein the oxide film includes a silicon oxide film region in which the oxygen is missing as compared with stoichiometric composition in part at least.

4. An oxide film filled structure, comprising:
a foundation having a depressed portion; and
an oxide film which is formed in the depressed portion and includes silicon and oxygen;
wherein the oxide film includes a silicon oxide film region where the silicon is superfluous in part at least as compared with stoichiometric composition.

5. A semiconductor device which has the oxide film filled structure according to claim 1.

6. A semiconductor device according to claim 5, wherein
the depressed portion is formed over a silicon substrate.

7. A semiconductor device according to claim 5, wherein
one of the silicon oxide film region of silicon-richness, the silicon oxide film region where an index of refraction exceeds 1.465, the silicon oxide film region in which the oxygen is missing, and the silicon oxide film region where silicon is superfluous is formed at least at a bottom of the depressed portion.

8. A semiconductor device according to claim 6, wherein
the oxide film is an element isolation film.

9. A semiconductor device according to claim 6, wherein
the oxide film is an interlayer insulation film.

10. A semiconductor device according to claim 5, wherein
fluorine is included in the oxide film.

11. A semiconductor device according to claim 5, wherein
in the oxide film formed in the depressed portion, a silicon oxide film which has stoichiometric composition is included.

12. A semiconductor device according to claim 11, wherein
the silicon oxide film which has stoichiometric composition is formed near an opening of the depressed portion.

13. An oxide film filling method, comprising the steps of:
(X) forming a depressed portion in a foundation; and
(Y) forming an oxide film including silicon and oxygen in the depressed portion;
wherein the step (Y) is a step which forms the oxide film including a silicon oxide film region of silicon-richness in part at least.

14. A manufacturing method of a semiconductor device according to claim 13,
wherein the step (Y) comprises a step of:
(Y-1) forming the oxide film using plasma CVD method according to a condition whose flow rate ratio of O₂/SiH₄ is less than 1.5.

15. A manufacturing method of a semiconductor device according to claim 13,
wherein the step (Y) comprises a step of:
(Y-2) forming the oxide film using plasma CVD method using hydrogen gas according to a condition whose flow rate ratio of O₂/SiH₄ is less than 2.

16. A manufacturing method of a semiconductor device, comprising a step of:
forming an oxide film in a depressed portion which a foundation layer has by the oxide film filling method according to claim 13,
wherein
the step (Y) is a step which forms in the depressed portion the oxide film comprising the silicon oxide film region of silicon-richness using a plasma CVD device.

17. A manufacturing method of a semiconductor device according to claim 16, wherein
the step (Y) is given, when forming the oxide film to a predetermined depth from a bottom of the depressed portion at least.

18. A manufacturing method of a semiconductor device according to claim 14, wherein
the step (Y-1) makes the flow rate ratio increase as a site approaches an opening from a bottom of the depressed portion.

19. A manufacturing method of a semiconductor device according to claim 15, wherein
the step (Y-2) makes the flow rate ratio increase as a site approaches an opening from a bottom of the depressed portion.

20. A manufacturing method of a semiconductor device according to claim 16, wherein
the step (Y) is a step forming the oxide film, performing a film formation process and a sputtering process simultaneously, and makes a rate of the sputtering over the film formation decrease as a site approaches an opening from a bottom of the depressed portion.

21. A manufacturing method of a semiconductor device according to claim 16, wherein the step (Y) comprises a step of:
performing an etching process to near an opening of the depressed portion.

22. A manufacturing method of a semiconductor device according to claim 16, further comprising a step of
(T) oxidizing the oxide film by oxygen plasma treatments using gas in which at least oxygen is included after the step (Y).

23. A manufacturing method of a semiconductor device according to claim 22, wherein the step (T) comprises a step of
doing the plasma oxidation about the oxide film near an opening of the depressed portion.

24. A manufacturing method of a semiconductor device according to claim 22, wherein
the step (Y), and the step (T) are carried out within a same apparatus.

25. A manufacturing method of a semiconductor device according to claim 22, wherein
the step (T) is the oxygen plasma treatments which use oxygen ions or oxygen radicals.

26. A manufacturing method of a semiconductor device according to claim 16, wherein
the step (Y) is a step which forms the oxide film, performing a deposition process and a sputtering process simultaneously, and fluorine is included in raw gas.

27. A manufacturing method of a semiconductor device according to claim 16, wherein
the step (Y) is a step which forms the oxide film, performing a deposition process and a sputtering process simultaneously, and one of hydrogen and helium is included in raw gas.

28. A manufacturing method of a semiconductor device according to claim 16, wherein
the step (Y) is a step which forms the oxide film, performing a film formation process and a sputtering process simultaneously, and argon is included in raw gas.
